(19) United States
(12) Patent Application Publication
(10) Pub. No.: US 2025/0129273 A1
(43) Pub. Date: Apr. 24, 2025

(54) BUFFER STRUCTURE, DISPLAY MODULE, AND DISPLAY DEVICE

(71) Applicants: Hefei Visionox Technology Co., Ltd., Hefei (CN); Visionox Technology Inc., Kunshan (CN)

(72) Inventors: Xuelin FAN, Hefei (CN); Zhan SUN, Kunshan (CN)

(73) Assignees: Hefei Visionox Technology Co., Ltd., Hefei (CN); Visionox Technology Inc., Kunshan (CN)

(21) Appl. No.: 19/006,146

(22) Filed: Dec. 30, 2024

(30) Foreign Application Priority Data
Jan. 15, 2024 (CN) 202410059240.2

(51) Int. Cl. C09J 11/04; B32B 3/26; B32B 7/12; C09J 7/10; C09J 7/38

(52) U.S. Cl. CPC C09J 11/04; B32B 3/266; B32B 7/12; C09J 7/10; C09J 7/38; B32B 2307/7376; B32B 2457/20; C09J 2203/326; C09J 2301/208; C09J 2301/302; C09J 2301/314; C09J 2301/408; C09J 2483/00

(57) ABSTRACT

The present application provides a buffer structure, a display module, and a display device. The buffer structure includes a silicon-based pressure-sensitive adhesive layer, and the silicon-based pressure-sensitive adhesive layer is doped with graphene. Doping the graphene in the silicon-based pressure-sensitive adhesive layer allows thermal conductivity of the buffer structure to be effectively improved, and allows mechanical strength of the buffer structure to be enhanced, thereby improving buffer performance of the buffer structure and improving a film printing effect.

### CROSS-REFERENCE TO RELATED APPLICATIONS

The present disclosure claims a priority to Chinese Patent Application No. 202410059240.2, filed on Jan. 15, 2024, which is incorporated by reference in its entirety for all purposes as fully set forth herein.

### TECHNICAL FIELD

The present application relates to the field of display technologies, and specifically, to a buffer structure, a display module, and a display device.

### BACKGROUND ART

With the development of display technologies, how to balance the buffer performance of the back of a display module and film printing performance has become a key problem in display module development.

### SUMMARY OF THE INVENTION

In view of this, the present application seeks to provide a buffer structure, a display module, and a display device, which can effectively reduce a thickness of a display panel.

According to a first aspect, the present application provides a buffer structure, including:
a silicon-based pressure-sensitive adhesive layer, where
the silicon-based pressure-sensitive adhesive layer is doped with a graphene.

Optionally, the graphene includes a first-type graphene and/or a second-type graphene, where the first-type graphene includes an unmodified graphene; and the second-type graphene includes a modified graphene; or
optionally, the graphene includes the first-type graphene and the second-type graphene, where in the silicon-based pressure-sensitive adhesive layer, a content of the second-type graphene is greater than that of the first-type graphene.

Optionally, the content of the first-type graphene ranges from 4 wt % to 10 wt %; or
optionally, the content of the first-type graphene is 6 wt %.

Optionally, the content of the second-type graphene ranges from 5 wt % to 15 wt %;
optionally, the content of the second-type graphene is 11 wt %; and
optionally, the modified graphene includes graphene grafted with siloxane.

Optionally, the silicon-based pressure-sensitive adhesive layer includes a first sub-layer and a second sub-layer that are arranged in a stacked manner;
optionally, a content of the graphene in the first sub-layer is different from that in the second sub-layer; and
optionally, a film thickness of the first sub-layer is different from that of the second sub-layer.

Optionally, the silicon-based pressure-sensitive adhesive layer further includes a third sub-layer, and the third sub-layer is located on a side of the second sub-layer facing away from the first sub-layer;
optionally, a content of the graphene in the third sub-layer is different from that in the second sub-layer;
optionally, a film thickness of the third sub-layer is different from that of the second sub-layer;
optionally, the film thickness of the second sub-layer is greater than that of the first sub-layer and greater than that of the third sub-layer;
optionally, a thickness of the first sub-layer ranges from 5 μm to 40 μm;
a thickness of the second sub-layer ranges from 70 μm to 140 μm;
a thickness of the third sub-layer ranges from 5 μm to 40 μm; and
optionally, thermal conductivity of the second sub-layer is greater than that of the first sub-layer and greater than that of the third sub-layer.

Optionally, the first sub-layer includes a first silicon-based pressure-sensitive adhesive layer; the second sub-layer includes a second silicon-based pressure-sensitive adhesive layer or a thermally conductive layer, and a content of silicon-based pressure-sensitive adhesive in the thermally conductive layer is 0; and the third sub-layer includes a third silicon-based pressure-sensitive adhesive layer;
optionally, silicon-based pressure-sensitive adhesive in the first silicon-based pressure-sensitive adhesive layer, the second silicon-based pressure-sensitive adhesive layer, and the third silicon-based pressure-sensitive adhesive layer includes silica gel;
optionally, the silica gel in the first silicon-based pressure-sensitive adhesive layer and the third silicon-based pressure-sensitive adhesive layer is platinum-catalyzed silica gel;
the silica gel in the second silicon-based pressure-sensitive adhesive layer is silica gel in which hydroxyl groups react with each other;
optionally, when the silicon-based pressure-sensitive adhesive layer is doped with the second-type graphene, a content of the second-type graphene doped in the second sub-layer ranges from 12 wt % to 15 wt %;
a content of the second-type graphene doped in the first silicon-based pressure-sensitive adhesive layer ranges from 5 wt % to 11 wt %;
a content of the second-type graphene doped in the third silicon-based pressure-sensitive adhesive layer ranges from 5 wt % to 11 wt %;
optionally, when the silicon-based pressure-sensitive adhesive layer is doped with the first-type graphene, a content of the first-type graphene doped in the second sub-layer ranges from 8 wt % to 10 wt %;
a content of the first-type graphene doped in the first silicon-based pressure-sensitive adhesive layer ranges from 4 wt % to 7 wt %;
a content of the first-type graphene doped in the third silicon-based pressure-sensitive adhesive layer ranges from 4 wt % to 7 wt %; and
optionally, a material of the thermally conductive layer includes a modified thermoplastic polyurethane elastomer.

Optionally, the second sub-layer is doped with a thermally conductive filler;
optionally, the thermally conductive filler includes at least one of boron nitride, aluminum nitride, and silicon carbide; and
optionally, a content of the thermally conductive filler in the second sub-layer ranges from 20% to 80%.

Optionally, the silicon-based pressure-sensitive adhesive layer includes a plurality of accommodation holes; and
the plurality of accommodation holes are filled with the graphene.

Optionally, silicon-based pressure-sensitive adhesive in the silicon-based pressure-sensitive adhesive layer includes silica gel; and
optionally, a thickness of the silicon-based pressure-sensitive adhesive layer ranges from 80 μm to 150 μm.

According to a second aspect, the present application provides a buffer structure, including:
a silicon-based pressure-sensitive adhesive body; and
a target dopant, where the target dopant is doped in the silicon-based pressure-sensitive adhesive body, and a target parameter of the target dopant is greater than that of the silicon-based pressure-sensitive adhesive body, where the target parameter includes a Young's modulus and/or a thermal conductivity;
optionally, the silicon-based pressure-sensitive adhesive body includes a silica gel body;
optionally, the target dopant includes graphene;
optionally, the graphene includes first-type graphene and/or second-type graphene, where
the first-type graphene includes unmodified graphene; and
the second-type graphene includes modified graphene; or
optionally, the graphene includes first-type graphene and second-type graphene, where in the silicon-based pressure-sensitive adhesive body, a content of the second-type graphene is greater than that of the first-type graphene.

Optionally, the silicon-based pressure-sensitive adhesive body includes a first body and a second body that are arranged in a stacked manner; and
a content of the target dopant in the first body is different from that in the second body.

Optionally, the silicon-based pressure-sensitive adhesive body further includes a third body; and the third body is located on a side of the second body facing away from the first body;
optionally, a content of the target dopant in the third body is different from that in the second body; and
optionally, a target parameter of the second body is greater than that of the first body and greater than that of the third body.

According to a third aspect, the present application further provides a display module, including the buffer structure according to the first aspect of the present application;
optionally, further including a display panel located on a side of the buffer structure; and
optionally, further including a support layer located on a side of the buffer structure facing away from the display panel.

According to a fourth aspect, the present application further provides a display device, including a display module according to the third aspect of the present application.

In solutions of the present application, the buffer structure includes the silicon-based pressure-sensitive adhesive layer, and the silicon-based pressure-sensitive adhesive layer is doped with the graphene. Doping the graphene in the silicon-based pressure-sensitive adhesive layer allows thermal conductivity of the buffer structure to be effectively improved, and allows mechanical strength of the buffer structure to be enhanced, thereby improving buffer performance of the buffer structure and improving a film printing effect.

### BRIEF DESCRIPTION OF THE DRAWINGS

The above and other objects, features, and advantages of the present application will become more apparent from more detailed description of embodiments of the present application in conjunction with the accompanying drawings. The accompanying drawings are used to provide a further understanding of the embodiments of the present application and constitute a part of the specification. Together with the embodiments of the present application, the accompanying drawings are used to explain the present application and do not constitute a limitation on the present application. In the accompanying drawings, the same reference numerals generally represent the same components or steps.

FIG. 1 is a schematic diagram of a structure of a buffer structure according to an embodiment of the present application;

FIG. 2 is a schematic diagram of a structure of a buffer structure according to another embodiment of the present application;

FIG. 3 is a schematic diagram of a structure of a buffer structure according to another embodiment of the present application;

FIG. 4 is a schematic diagram of a structure of a buffer structure according to another embodiment of the present application;

FIG. 5 is a schematic diagram of a structure of a buffer structure according to another embodiment of the present application;

FIG. 6 is a schematic diagram of a structure of a buffer structure according to another embodiment of the present application;

FIG. 7 is a schematic diagram of a structure of a buffer structure according to another embodiment of the present application;

FIG. 8 is a schematic diagram of a structure of a display module according to an embodiment of the present application;

FIG. 9 is a schematic diagram of a structure of a display module according to another embodiment of the present application; and

FIG. 10 is a schematic diagram of a structure of a display device according to an embodiment of the present application.

### DETAILED DESCRIPTION OF EMBODIMENTS

Unless defined otherwise, the technical or scientific terms used in embodiments of the specification shall have the common meanings as understood by those of ordinary skill in the art to which the specification belongs. The terms “first”, “second”, and the like words used in the embodiments of the specification do not indicate any order, quantity, or importance, but are merely provided to avoid confusion of constituent elements.

Unless otherwise required in the context, throughout the specification, “a plurality” means “at least two,” and “including” is interpreted as being open-ended and inclusive, that is, “including, but not limited to”. In the description of the specification, the terms “an embodiment,” “some embodiments,” “exemplary embodiments,” “an example”, “a specific example”, “some examples”, or the like, are intended to indicate that specific features, structures, materials, or characteristics related to the embodiments or examples are included in at least one embodiment or example of the specification. The schematic expressions of the above terms do not necessarily refer to the same embodiments or examples.

The technical solutions in the embodiments of the specification will be clearly and completely described below in conjunction with the accompanying drawings in the embodiments of the specification. Apparently, the embodiments described are merely some rather than all of the embodiments of the specification. All other embodiments derived by those of ordinary skill in the art on the basis of the embodiments in the specification without creative efforts shall fall within the scope of protection of the specification.

With the development of display technologies, electronic products with a large screen, a high screen-to-body ratio, a curved screen, and a foldable screen have become a mainstream demand or configuration, accordingly, display modules are developing towards functionally integrated and ultra-thin and lightweight display modules, and this change trend leads to the increasing importance of buffer protection requirements of display modules.

Currently, buffer protection for a display module mainly depends on a buffer structure on the back of the display module, the buffer structure is mainly made of foam materials, but the foam materials have ordinary buffer performance, and an overall thickness of the foam materials is too large to improve the buffer performance of the back of the display module while achieving a weight reduction and thinning effect. There are also some buffer structures in the market that use silicon-based pressure-sensitive adhesive materials instead of foam materials, which can improve the buffer performance of the back of the display module, and can also achieve the weight reduction and thinning effect.

However, the inventors have found that the buffer structure made of silicon-based pressure-sensitive adhesive materials, while achieving the weight reduction and thinning effect, creates new problems, for example, the risk of film printing in such a buffer structure is significantly increased compared with a buffer structure made of foam materials. A display module with the buffer structure made of foam materials has a better film printing effect in a screen-off state, but a ball drop height onto the back of the display module is lower. In contrast, for a display module with the buffer structure made of silicon-based pressure-sensitive adhesive materials, its ball drop height onto the back is higher, buffer performance has been obviously improved, but the film printing effect is poor in a screen-off state. Therefore, how to balance the buffer performance of the back of a display module and film printing performance is an urgent technical problem to be solved.

To this end, the present application provides a solution capable of effectively improving the film printing effect. Graphene is doped in a silicon-based pressure-sensitive adhesive layer, and the doped graphene may be used to improve the characteristics of the silicon-based pressure-sensitive adhesive layer, so that the silicon-based pressure-sensitive adhesive layer doped with the graphene has a relatively obvious improvement in thermal conductivity and mechanical strength, thereby improving the buffer performance of the buffer structure and improving the film printing effect.

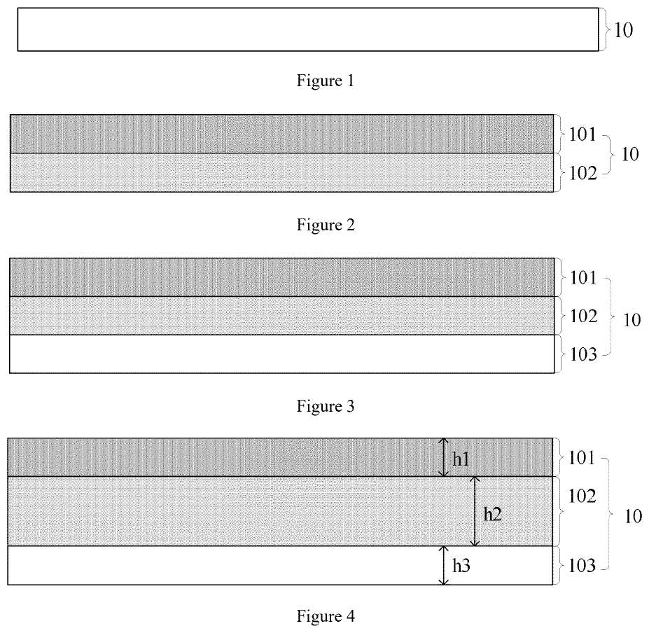

Specifically, as an optional implementation of the disclosure of the present application, embodiments of the present application provide a buffer structure. FIG. 1 is a schematic diagram of a structure of a buffer structure according to an embodiment of the present application, and as shown in FIG. 1, the buffer structure may include at least: a silicon-based pressure-sensitive adhesive layer 10, where the silicon-based pressure-sensitive adhesive layer 10 is doped with graphene.

It should be noted that graphene is one of the known materials with a highest strength, and it also has good toughness and is bendable. Graphene has a theoretical Young's modulus of 1.0 TPa and an inherent tensile strength of 130 GPa. Reduced graphene modified with hydrogen plasma also has an excellent strength, with an average modulus of up to 0.25 TPa. In addition, graphene has excellent thermal conductivity. Pure defect-free single-layer graphene has a thermal conductivity of up to 5300 W/mK, being a carbon material with a highest thermal conductivity by far, greater than that of a single-walled carbon nanotube (3500 W/mK) and a multi-walled carbon nanotube (3000 W/mK).

When applied, silicon-based pressure-sensitive adhesive is the host material of the silicon-based pressure-sensitive adhesive layer, and silica gel may be selected as the silicon-based pressure-sensitive adhesive.

Graphene is doped in the silicon-based pressure-sensitive adhesive layer 10, that is, graphene is doped in a silica gel system, which may utilize the graphene to improve the thermal conductivity of the silica gel system and improve its mechanical strength, thereby helping to improve the film printing effect.

The graphene may include first-type graphene and/or second-type graphene. The first-type graphene may include unmodified graphene; and the second-type graphene may include modified graphene.

The unmodified graphene may be pure graphene.

During implementation, the graphene may be the first-type graphene, or may be the second-type graphene, or may include both the first-type graphene and the second-type graphene.

Specifically, the silicon-based pressure-sensitive adhesive layer 10 may be doped with only the first-type graphene, and a content of the first-type graphene may be 4 wt % to 10 wt %. For example, the content of the first-type graphene may be 4 wt %, 5 wt %, 8 wt %, or 10 wt %.

When the silicon-based pressure-sensitive adhesive layer 10 is doped with the first-type graphene, along with the content of the first-type graphene increases, the Young's modulus and thermal conductivity of the silicon-based pressure-sensitive adhesive layer 10 also increase, and at the same time, the silicon-based pressure-sensitive adhesive layer is reduced in adhesion, does not change much in a buffer absorption rate, and has a relatively obvious improvement in the film printing effect. However, when the content of the first-type graphene in the silicon-based pressure-sensitive adhesive layer exceeds 10 wt %, a problem of uneven dispersion occurs. Therefore, when the first-type graphene is doped in the silicon-based pressure-sensitive adhesive layer 10, the content of the first-type graphene is maintained within the range of 4 wt % to 10 wt %, which may improve both the thermal conductivity and the buffer performance of the buffer structure and improve the film printing effect, and may also avoid the problem of uneven dispersion.

The buffer absorption rate refers to a minimum height value where a falling ball impacts on the back of the display module and then no sub bright pixels will appear after the buffer structure is applied in the display module.

Preferably, the content of the first-type graphene in the silicon-based pressure-sensitive adhesive layer 10 is 6 wt %.

In actual applications, the silicon-based pressure-sensitive adhesive layer 10 may alternatively be doped with only the second-type graphene.

Specifically, the content of the second-type graphene in the silicon-based pressure-sensitive adhesive layer 10 may range from 5 wt % to 15 wt %. For example, the content of the second-type graphene may be 5 wt %, 8 wt %, 10 wt %, 12%, or 15 wt %.

When the silicon-based pressure-sensitive adhesive layer 10 is doped with the second-type graphene, as the content of the second-type graphene increases, the Young's modulus and thermal conductivity of the silicon-based pressure-sensitive adhesive layer 10 also increase, and at the same time, the silicon-based pressure-sensitive adhesive layer is reduced in adhesion, does not change much in buffer performance on the back, and has a relatively obvious improvement in the film printing effect. Therefore, when the second-type graphene is doped in the silicon-based pressure-sensitive adhesive layer 10, the content of the second-type graphene is maintained within a range of 5 wt % to 15 wt %, which may make the buffer structure have better thermal conductivity and buffer performance, and also maintain sufficient adhesion.

Preferably, the content of the second-type graphene in the silicon-based pressure-sensitive adhesive layer 10 is 11 wt %.

In order to further verify that a graphene-doped silicon-based pressure-sensitive adhesive layer and a modified graphene-doped silicon-based pressure-sensitive adhesive layer have better thermal conductivity, buffer performance, and film printing effect, performance comparisons are performed below on conventional foam materials, conventional silica gel materials, silica gel materials doped with 5 wt % of graphene, and silica gel materials doped with 11 wt % of modified graphene, as shown in Table 1.

TABLE 1
Performance comparison results

| | | | | Silica gel doped | | Silica gel doped | |
|---|---|---|---|---|---|---|---|
| | | | | with 5 wt % of | | with 11 wt % of | |
| | Conventional | Conventional | | the first-type | | the second-type | |
| Comparison items | foam | silica gel | | graphene | | graphene | |
| Modulus at normal | NA | 189 | KPa | 195 | KPa | 166 | KPa |
| temperature | | | | | | | |
| Thermal | 0.02 w/mk | 0.13 | w/mk | 0.6 | w/mk | 1.1 | w/mk |
| conductivity | to 0.04 | | | | | | |
| | w/mk | | | | | | |
| Young's modulus | NA | 90 | KPa | 180 | KPa | 200 | KPa |
| Adhesion | 1600 gf/inch | 1600 | gf/inch | 1300 | gf/inch | 1100 | gf/inch |

| | | | | |
|---|---|---|---|---|
| Buffer absorption | 40% | 60% | 55% | 55% |
| rate | | | | |
| Film printing effect | 10N | 4N | 9N | 12N |

In the table, the film printing effect is a minimum pressure value when the back of the display module is squeezed by a φ3mm indenter and there is no poor film printing effect. A greater pressure value indicates a higher anti-film printing level.

It may be learned from Table 1 that, for the silica gel doped with 5 wt % of the first-type graphene and the silica gel doped with 11 wt % of the second-type graphene, both the thermal conductivity and the Young's modulus are obviously increased, the adhesion is weakened but does not change much, and the buffer absorption rate is almost unchanged; and compared with the silica gel not doped with graphene, the silica gel doped with the first-type graphene (i.e. the unmodified graphene) and the silica gel doped with the second-type graphene (i.e. the modified graphene) have a relatively obvious improvement in the film printing effect. It may be learned that doping the first-type graphene or the second-type graphene in the silicon-based pressure-sensitive adhesive layer may effectively improve the thermal conductivity and mechanical strength of the buffer structure, thereby improving the buffer performance, and further helping to improve the film printing effect, which takes into account the buffer performance and the film printing performance.

Certainly, the present application is not limited to this, and in some embodiments, the silicon-based pressure-sensitive adhesive layer 10 in the buffer structure may alternatively be doped with both the first-type graphene and the second-type graphene.

The content of the first-type graphene may be maintained at 4 wt % to 10 wt %. The content of the second-type graphene may be maintained at 5 wt % to 15 wt %. Doping of both the first-type graphene and the second-type graphene in the silicon-based pressure-sensitive adhesive layer 10 may further improve the buffer performance and thermal conductivity of the buffer structure and improve the film printing effect.

In order to further improve the buffer performance and thermal conductivity of the buffer structure, the content of the second-type graphene may be greater than that of the first-type graphene in the silicon-based pressure-sensitive adhesive layer.

Preferably, the content of the first-type graphene is 6 wt % and the content of the second-type graphene is 11 wt %.

In some embodiments, the modified graphene may include graphene grafted with siloxane.

Specifically, the modified graphene may be obtained from pure graphene by oxidative grafting modification.

During implementation, the modified graphene may be obtained from the following: pure graphene may first react with oxygen, polar groups such as —COOH are grafted onto end groups of the graphene, a silane coupling agent KH550 is added, and silane groups are grafted onto the graphene.

After the modified graphene is obtained, the modified graphene may be added to a silicon-based pressure-sensitive adhesive reaction system, and the modified graphene is grafted onto a side chain of the silicon-based pressure-sensitive adhesive, to obtain a silicon-based pressure-sensitive adhesive layer. In this way, the silicon-based pressure-sensitive adhesive layer doped with the modified graphene is obtained, and its thermal conductivity and buffer performance are obviously improved.

In some embodiments, the silicon-based pressure-sensitive adhesive layer 10 may include a first sub-layer 101 and a second sub-layer 102 that are arranged in a stacked manner, as shown in FIG. 2.

A content of graphene in the first sub-layer 101 is different from that in the second sub-layer 102.

For example, a content of first-type graphene in the first sub-layer 101 may be 8 wt % and a content of the first-type graphene in the second sub-layer 102 may be 9 wt %. For another example, a content of second-type graphene in the first sub-layer 101 may be 11 wt % and a content of the second-type graphene in the second sub-layer 102 may be 13 wt %.

Setting the first sub-layer 101 and the second sub-layer 102 to have different contents of graphene may make two sides of the silicon-based pressure-sensitive adhesive layer 10 have different adhesion, so that different adhesion requirements of different sides of the buffer structure may be met while the buffer performance and mechanical strength of the buffer structure may be improved as much as possible. In addition, the consumption of the graphene and the preparation costs of the buffer structure may be further reduced.

Certainly, the description is merely made in the specification of the present application by using different contents of the graphene in the first sub-layer 101 and the second sub-layer 102 as an example, but the present application is not limited thereto, and in some other embodiments, the content of the graphene in the first sub-layer 101 may alternatively be the same as that in the second sub-layer 102.

In some embodiments, the first sub-layer 101 and the second sub-layer 102 may have the same film thickness or different film thicknesses.

When the first sub-layer 101 and the second sub-layer 102 have different film thicknesses, the film thicknesses of the two sub-layers may be adjusted based on different performance of the two sub-layers. For example, in order that the first sub-layer 101 has a higher mechanical strength than that of the second sub-layer 102, the first sub-layer 101 may be set to have a film thickness greater than that of the second sub-layer 102, thereby increasing the overall mechanical strength of the buffer structure.

In some embodiments, the silicon-based pressure-sensitive adhesive layer 10 may further include a third sub-layer 103, as shown in FIG. 3. The third sub-layer 103 is located on a side of the second sub-layer 102 facing away from the first sub-layer 101.

During implementation, a content of the graphene in the third sub-layer is different from that in the second sub-layer.

For example, a content of the first-type graphene in the second sub-layer 102 may be 9 wt %, and a content of the first-type graphene in the third sub-layer 103 may be 8 wt %. For another example, a content of the second-type graphene in the second sub-layer 102 may be 11 wt % and a content of the second-type graphene in the third sub-layer 103 may be 14 wt %.

The content of the graphene in the second sub-layer 102 is set to be different from that in the third sub-layer 103, which may help to adjust the characteristics of the buffer structure. For example, two sides of the buffer structure need to maintain specific adhesion, therefore, the first sub-layer 101 and the third sub-layer 103 need to have specific adhesion, and however, the second sub-layer 102 as an intermediate layer has no rigid requirement to have specific adhesion, so that it is possible to improve the mechanical strength or thermal conductivity of the buffer structure by increasing the mechanical strength or thermal conductivity of the second sub-layer 102, with no need to consider the adhesion of the second sub-layer 102.

Certainly, the description is merely made in the specification of the present application by using an example in which the first sub-layer and the second sub-layer in which the contents of the graphene are different, and/or the second sub-layer and the third sub-layer in which the contents of the graphene are different, but the present application is not limited thereto, and in some other embodiments, the content of the graphene in the first sub-layer may be the same as that in the second sub-layer, and/or the content of the graphene in the second sub-layer may be the same as that in the third sub-layer.

In some embodiments, the third sub-layer and the second sub-layer may have different film thicknesses.

Specifically, the film thicknesses of the third sub-layer and the second sub-layer may be adjusted according to different performance requirements of the two sub-layers.

During implementation, the film thickness of the second sub-layer may be greater than the film thickness of the first sub-layer and greater than the film thickness of the third sub-layer.

Because the second sub-layer is located in an intermediate film layer of the buffer structure, the buffer performance and adhesion of the second sub-layer may be significantly different from those of the first sub-layer and the third sub-layer.

For example, the buffer performance of the buffer structure needs to be adjusted by relying on the second sub-layer, the film thickness of the second sub-layer may be increased while increasing the mechanical strength of the second sub-layer, such that the film thickness of the second sub-layer is greater than the film thickness of the third sub-layer and the film thickness of the first sub-layer. This results in an obvious improvement in the buffer performance of the buffer structure. The first sub-layer and the third sub-layer only need to have strong adhesion, and the film thicknesses of the first sub-layer and the third sub-layer do not need to be too large.

During particular implementation, the thickness of the first sub-layer may be set to be within a range of 5 μm to 40 μm; the thickness of the second sub-layer may be set to be within a range of 70 μm to 140 μm; and the thickness of the third sub-layer may be set to be within a range of 5 μm to 40 μm.

For example, as shown in FIG. 4, both the thickness h1 of the first sub-layer 101 and the thickness h3 of the third sub-layer 103 may be set to 5 μm, the thickness h2 of the second sub-layer 102 may be set to 140 μm. The first sub-layer 101, the second sub-layer 102, and the third sub-layer 103 are sequentially arranged in a stacked manner, and the buffer structure is a three-layer silicon-based pressure-sensitive adhesive layer structure having a thickness of 150 μm, which may not only prevent the buffer structure from being too thick to hinder the thinning of the display module, but also prevent the buffer structure from being too thin to cause insufficient buffer performance. The first sub-layer 101, the second sub-layer 102, and the third sub-layer 103 are sequentially arranged in a stacked manner, so that the buffer structure has the same adhesion as the first sub-layer 101 and the third sub-layer 103, and also has the same thermal conductivity and buffer performance as the second sub-layer 102.

In this case, the second sub-layer 102 is set to have a large thickness and the thickness of the second sub-layer 102 is greater than both the thickness of the first sub-layer 101 and the thickness of the third sub-layer 103, which may allow the buffer structure to have a high thermal conductivity and buffer performance while having strong adhesion.

In addition, it is possible to set thermal conductivity of the second sub-layer of the buffer structure to be greater than thermal conductivity of the first sub-layer and greater than thermal conductivity of the third sub-layer.

When the thickness of the second sub-layer is greater than thicknesses of the other sub-layers, a larger thermal conductivity of the second sub-layer located in the intermediate layer in the buffer structure leads to a better thermal conductivity of the buffer structure. The thermal conductivity of the second sub-layer of the buffer structure is set to be greater than the thermal conductivity of the first sub-layer and greater than the thermal conductivity of the third sub-layer, which effectively improves the thermal conductivity of the buffer structure.

In some embodiments, the first sub-layer may include a first silicon-based pressure-sensitive adhesive layer; the second sub-layer may include a second silicon-based pressure-sensitive adhesive layer or a thermally conductive layer; and the third sub-layer may include a third silicon-based pressure-sensitive adhesive layer.

When the second sub-layer is a thermally conductive layer, a content of silicon-based pressure-sensitive adhesive in the thermally conductive layer is 0.

In other words, main adhesive layers of the first sub-layer, the second sub-layer, and the third sub-layer may all be silicon-based pressure-sensitive adhesive; or the host material of the first sub-layer and the third sub-layer may be silicon-based pressure-sensitive adhesive, and the host material of the second sub-layer is not silicon-based pressure-sensitive adhesive.

During implementation, silicon-based pressure-sensitive adhesive in the first silicon-based pressure-sensitive adhesive layer, the second silicon-based pressure-sensitive adhesive layer, and the third silicon-based pressure-sensitive adhesive layer may include silica gel.

The silica gel in the first silicon-based pressure-sensitive adhesive layer and the third silicon-based pressure-sensitive adhesive layer may be platinum-catalyzed silica gel; and the silica gel in the second silicon-based pressure-sensitive adhesive layer may be silica gel in which hydroxyl groups react with each other.

Specifically, the silica gel in the first silicon-based pressure-sensitive adhesive layer and the third silicon-based pressure-sensitive adhesive layer are platinum-catalyzed silica gel, and such silica gel is adhesive in surface, and can be used to adhere copper foil (a support layer) and a screen body (a display panel). The silica gel in the second silicon-based pressure-sensitive adhesive layer may be silica gel in which hydroxyl groups react with each other, and such silica gel is not adhesive, but has excellent buffer performance, and has a high Young's modulus and a good film printing effect. In this way, silica gel layers with a three-layer structure may combine excellent ball drop performance onto its back with an excellent film printing effect, thereby further improving the buffer performance of the buffer structure and improving the film printing effect.

In some embodiments, in order to further enhance the buffer performance of the buffer structure and improve the film printing effect, when the second-type graphene is doped in the silicon-based pressure-sensitive adhesive layer, a content of the second-type graphene doped in the second sub-layer (the second silicon-based pressure-sensitive adhesive layer or the thermally conductive layer) may range from 12 wt % to 15 wt %; a content of the second-type graphene doped in the first silicon-based pressure-sensitive adhesive layer may range from 5 wt % to 11 wt %; and a content of the second-type graphene doped in the third silicon-based pressure-sensitive adhesive layer may range from 5 wt % to 11 wt %.

The second sub-layer (the second silicon-based pressure-sensitive adhesive layer or the thermally conductive layer) is located between the first silicon-based pressure-sensitive adhesive layer and the third silicon-based pressure-sensitive adhesive layer, and low requirements on are imposed on adhesion of the second sub-layer. The content of the second-type graphene in the second sub-layer is controlled at 12 wt % to 15 wt %, which may make the second sub-layer have high thermal conductivity and a strong Young's modulus, thereby improving the thermal conductivity and Young's modulus of the whole buffer structure. In contrast, the first silicon-based pressure-sensitive adhesive layer and the third silicon-based pressure-sensitive adhesive layer are located on two sides of the second sub-layer, and need to have specific adhesion, so as to adhere the copper foil and the screen body. Therefore, the content of the second-type graphene doped in the first silicon-based pressure-sensitive adhesive layer is controlled at 5 wt % to 11 wt %; and the content of the second-type graphene doped in the third silicon-based pressure-sensitive adhesive layer is controlled at 5 wt % to 11 wt %, which can ensure that the buffer structure has specific adhesion, and can also ensure that it has high thermal conductivity and buffer performance.

During implementation, the first silicon-based pressure-sensitive adhesive layer and the third silicon-based pressure-sensitive adhesive layer may be set as two silicon-based pressure-sensitive adhesive layers made of the same material, so that the first silicon-based pressure-sensitive adhesive layer and the third silicon-based pressure-sensitive adhesive layer have the same characteristic. In this way, it can be ensured that two sides of the buffer structure have the same adhesion, thermal conductivity, and buffer performance.

Similarly, when the silicon-based pressure-sensitive adhesive layer is doped with the first-type graphene, a content of the first-type graphene doped in the second sub-layer (the second silicon-based pressure-sensitive adhesive layer or the thermally conductive layer) may range from 8 wt % to 10 wt %; a content of the first-type graphene doped in the first silicon-based pressure-sensitive adhesive layer may range from 4 wt % to 7 wt %; and a content of the first-type graphene doped in the third silicon-based pressure-sensitive adhesive layer 103 may range from 4 wt % to 7 wt %.

Compared to the case in which the content of the doped first-type graphene ranges from 4 wt % to 7 wt %, in the case in which the content of the doped first-type graphene ranges from 8 wt % to 10 wt %, the silicon-based pressure-sensitive adhesive layer has lower adhesion, but has an increased thermal conductivity, Young's modulus, and film printing effect. Therefore, the content of the first-type graphene in the second sub-layer is controlled at 8 wt % to 10 wt %, and the content of the first-type graphene doped in the first silicon-based pressure-sensitive adhesive layer is controlled at 4 wt % to 7 wt %; and the content of the first-type graphene doped in the third silicon-based pressure-sensitive adhesive layer is controlled at 4 wt % to 7 wt %, which can ensure that the buffer structure has specific adhesion, and can also ensure that it has high thermal conductivity and buffer performance.

In some embodiments, the second sub-layer (the second silicon-based pressure-sensitive adhesive layer or the thermally conductive layer) may alternatively be doped with a thermally conductive filler.

Specifically, the second sub-layer may be doped with only a thermally conductive filler, and is not doped with graphene.

The thermally conductive filler may include at least one of boron nitride (BN), aluminum nitride (ALN), and silicon carbide (SiC).

The boron nitride has chemical corrosion resistance, has a thermal conductivity ranging from 20 w/mk to 200 w/mk, has good thermal conductivity, and is a super hard material with a hardness second only to that of diamond. The boron nitride is used as a thermally conductive filler, which may ensure that the second sub-layer has good thermal conductivity and strong mechanical strength, thus ensuring that the buffer structure has good thermal conductivity and buffer performance.

As a solid nitride of aluminum, the aluminum nitride has a thermal conductivity ranging from 20 w/mk to 321 w/mk, also has good thermal conductivity, and is a very hard material with a Mohs hardness ranging from 9 to 10. The aluminum nitride is used as a thermally conductive filler, which may also ensure that the second sub-layer has good thermal conductivity and strong mechanical strength, thus ensuring that the buffer structure has good thermal conductivity and buffer performance.

Silicon carbide has a thermal conductivity ranging from 120 w/mk to 200 w/mk and a Mohs hardness up to 9.2 to 9.3, has good thermal conductivity and strong hardness, and is also one of the preferred materials for thermally conductive fillers, which may also ensure that the second sub-layer has good thermal conductivity and strong mechanical strength, thus ensuring that the buffer structure has good thermal conductivity and buffer performance.

When the second sub-layer (the second silicon-based pressure-sensitive adhesive layer or the thermally conductive layer) is doped with a thermally conductive filler, a content of the thermally conductive filler in the second sub-layer may range from 20% to 80%.

For example, the second sub-layer may be doped with 60% of boron nitride, and the thermal conductivity of the buffer structure may be improved by using the second sub-layer doped with 60% of boron nitride; for another example, the second sub-layer may be doped with 80% of aluminum nitride; and for still another example, the second sub-layer may be doped with 50% of silicon carbide.

It should be noted that the description is merely made in the specification of the present application by using doping only a thermally conductive filler in the second sub-layer as an example, but the present application is not limited thereto. In some other embodiments, graphene may also be doped in the second sub-layer doped with a thermally conductive filler. For a content and composition of the doped graphene, reference may be made to the graphene as described in any of the above embodiments, and details are not described herein again.

In some embodiments, a material of the thermally conductive layer may include a modified thermoplastic polyurethane elastomer.

The modified thermoplastic polyurethane elastomer has excellent integrated performance of high strength, high toughness, abrasion resistance, and high thermal conductivity. The modified thermoplastic polyurethane elastomer is used as the material for the thermally conductive layer, and the thermally conductive layer is doped with the above-mentioned thermally conductive filler and/or the above-mentioned graphene, which may ensure that the thermally conductive layer has good thermal conductivity and strong mechanical strength, thus ensuring that the buffer structure has good thermal conductivity and buffer performance.

Certainly, the description is merely made in the specification of the present application by using the material (including a modified thermoplastic polyurethane elastomer) of the thermally conductive layer as an example, but the present application is not limited thereto, and in some other embodiments, the material of the thermally conductive layer may alternatively be another material with excellent thermal conductivity and large hardness, which are not enumerated herein.

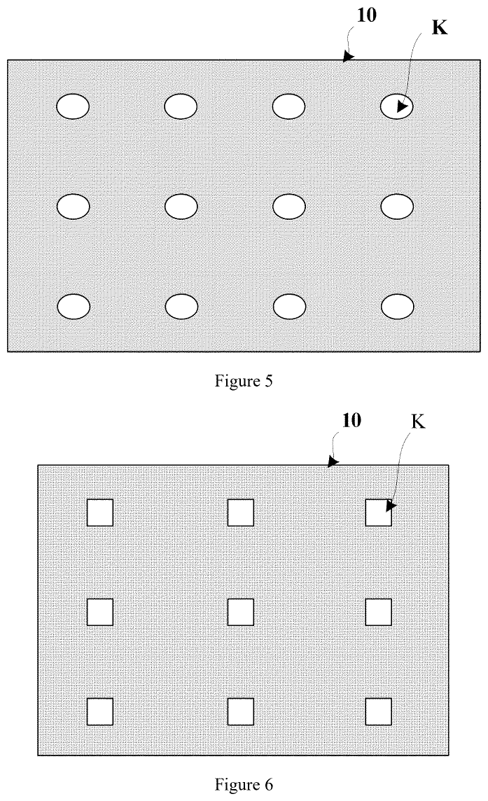

In some embodiments, as shown in FIG. 5, the silicon-based pressure-sensitive adhesive layer 10 may include a plurality of accommodation holes K; and the plurality of accommodation holes K are filled with the graphene.

During implementation, the plurality of accommodation holes K may be evenly

distributed on the silicon-based pressure-sensitive adhesive layer 10. The accommodation holes K may run through the silicon-based pressure-sensitive adhesive layer 10, and the accommodation holes K are evenly filled with the graphene.

Because the graphene (the first-type graphene or the second-type graphene) has large thermal conductivity and mechanical strength, the filling of the accommodation holes K with the graphene may effectively improve the thermal conductivity and mechanical strength of the buffer structure.

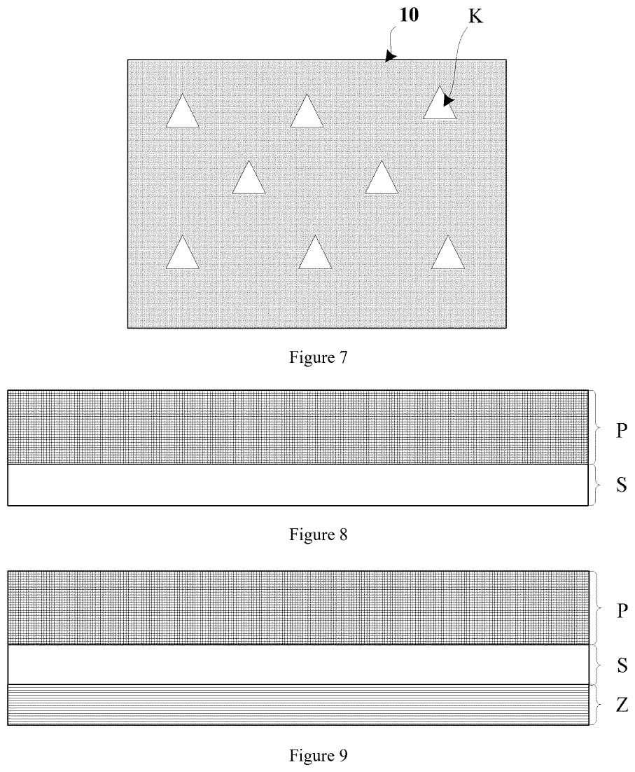

During application, a cross-sectional shape of the accommodation hole K may be circular, but the present application is not limited thereto. In some other embodiments, the cross-sectional shape of the accommodation hole K may alternatively be another shape. As shown in FIG. 6, the cross-sectional shape of the accommodation hole K may be rectangular, or as shown in FIG. 7, the cross-sectional shape of the accommodation hole K is triangular, which may be set according to actual requirements, and this is not specifically limited herein.

In some embodiments, a thickness of the silicon-based pressure-sensitive adhesive layer 10 may range from 80 μm to 150 μm.

The thickness of the silicon-based pressure-sensitive adhesive layer 10 is controlled at 80 μm to 150 μm, which can not only ensure that the silicon-based pressure-sensitive adhesive layer 10 has a specific thickness, thus making the buffer structure have sufficient mechanical strength and buffer performance, but also avoid imposing a burden on the development of lighter and thinner display modules due to an excessive thickness.

As another optional implementation of the disclosure of the present application, embodiments of the present application further provide a buffer structure, and the buffer structure may include: a silicon-based pressure-sensitive adhesive body; and a target dopant, where the target dopant is doped in the silicon-based pressure-sensitive adhesive body, and a target parameter of the target dopant is greater than that of the silicon-based pressure-sensitive adhesive body, where the target parameter includes a Young's modulus and/or a thermal conductivity.

In this embodiment, the target dopant with the target parameter greater than that of the silicon-based pressure-sensitive adhesive body is doped in the silicon-based pressure-sensitive adhesive body, thereby enhancing the target parameter of the buffer structure, so that the buffer structure has an obvious increase in the Young's modulus and/or thermal conductivity.

Specifically, the silicon-based pressure-sensitive adhesive body may include a silica gel body.

The silica gel is used as a host material of the buffer structure, the target dopant is doped in the buffer structure, thereby improving the thermal conductivity and Young's modulus of the silica gel body based on the characteristics of the silica gel, and this allows the buffer structure to have good thermal conductivity, buffer performance, and film printing effect.

The target dopant may include graphene.

Graphene is doped in the silicon-based pressure-sensitive adhesive body, and the doped graphene may be used to improve the characteristics of the silicon-based pressure-sensitive adhesive body, so that the silicon-based pressure-sensitive adhesive body doped with the graphene has a relatively obvious improvement in thermal conductivity and mechanical strength, thus improving the buffer performance of the buffer structure and improving the film printing effect.

The graphene may include first-type graphene and/or second-type graphene. The first-type graphene may include unmodified graphene; and the second-type graphene may include modified graphene.

The unmodified graphene may be pure graphene.

During implementation, the graphene may be the first-type graphene, or may be the second-type graphene, or may include both the first-type graphene and the second-type graphene.

Specifically, the silicon-based pressure-sensitive adhesive body may be doped with only the first-type graphene, and a content of the first-type graphene may be 4 wt % to 10 wt %. For example, the content of the first-type graphene may be 4 wt %, 5 wt %, 8 wt %, or 10 wt %.

When the silicon-based pressure-sensitive adhesive body is doped with the first-type graphene, as the content of the first-type graphene increases, the Young's modulus and thermal conductivity of the silicon-based pressure-sensitive adhesive body also increase, and at the same time, the silicon-based pressure-sensitive adhesive body is reduced in adhesion, does not change much in buffer performance on the back, and has a relatively obvious improvement in the film printing effect. However, when the content of the first-type graphene in the silicon-based pressure-sensitive adhesive body exceeds 10 wt %, a problem of uneven dispersion occurs. Therefore, when the first-type graphene is doped in the silicon-based pressure-sensitive adhesive body, the content of the first-type graphene is maintained within the range of 4 wt % to 10 wt %, which may improve both the thermal conductivity and the buffer performance of the buffer structure and improve the film printing effect, and may also avoid the problem of uneven dispersion.

Preferably, the content of the first-type graphene in the silicon-based pressure-sensitive adhesive body is 6 wt %.

In actual applications, the silicon-based pressure-sensitive adhesive body may alternatively be doped with only the second-type graphene.

Specifically, the content of the second-type graphene in the silicon-based pressure-sensitive adhesive body may range from 5 wt % to 15 wt %. For example, the content of the second-type graphene may be 5 wt %, 8 wt %, 10 wt %, 12%, or 15 wt %.

When the silicon-based pressure-sensitive adhesive body is doped with the second-type graphene, as the content of the second-type graphene increases, the Young's modulus and thermal conductivity of the silicon-based pressure-sensitive adhesive body also increase, and at the same time, the silicon-based pressure-sensitive adhesive body is reduced in adhesion, does not change much in buffer performance on the back, and has a relatively obvious improvement in the film printing effect. Therefore, when the second-type graphene is doped in the silicon-based pressure-sensitive adhesive body, the content of the second-type graphene is maintained within a range of 5 wt % to 15 wt %, which may make the buffer structure have better thermal conductivity and buffer performance, and also maintain sufficient adhesion.

Preferably, the content of the second-type graphene in the silicon-based pressure-sensitive adhesive body is 11 wt %.

Certainly, the present application is not limited to this, and in some embodiments, the silicon-based pressure-sensitive adhesive body in the buffer structure may alternatively be doped with both the first-type graphene and the second-type graphene.

The content of the first-type graphene may be maintained at 4 wt % to 10 wt %. The content of the second-type graphene may be maintained at 5 wt % to 15 wt %. Doping of both the first-type graphene and the second-type graphene in the silicon-based pressure-sensitive adhesive body may further improve the buffer performance and thermal conductivity of the buffer structure and improve the film printing effect.

In order to further improve the buffer performance and thermal conductivity of the buffer structure, the content of the second-type graphene may be greater than that of the first-type graphene in the silicon-based pressure-sensitive adhesive body.

Preferably, the content of the first-type graphene is 6 wt % and the content of the second-type graphene is 11 wt %.

In some embodiments, the modified graphene may include graphene grafted with siloxane.

During implementation, the modified graphene may be obtained from the following: unmodified graphene may first react with oxygen, polar groups such as —COOH are grafted onto end groups of the unmodified graphene, a silane coupling agent KH550 is added, and silane groups are grafted onto the graphene.

After the modified graphene is obtained, the modified graphene may be added to a silica gel reaction system, and the modified graphene is grafted onto a side chain of the silica gel, to obtain a buffer structure. In this way, the silicon-based pressure-sensitive adhesive body doped with the modified graphene is obtained, and its thermal conductivity and buffer performance are obviously improved.

In some embodiments, the silicon-based pressure-sensitive adhesive body may include a first body and a second body that are arranged in a stacked manner; and a content of the target dopant in the first body is different from that in the second body.

For example, a content of the first-type graphene in the first body may be 8 wt % and a content of the first-type graphene in the second body may be 9 wt %. For another example, a content of the second-type graphene in the first body may be 11 wt % and a content of the second-type graphene in the second body may be 13 wt %.

Setting the first body and the second body to have different contents of the target dopant may make two sides of the silicon-based pressure-sensitive adhesive body have different adhesion, so that different adhesion requirements of different sides of the buffer structure may be met while the buffer performance and mechanical strength of the buffer structure may be improved as much as possible. In addition, the consumption of the target dopant and the preparation costs of the buffer structure may be further reduced.

In some embodiments, the silicon-based pressure-sensitive adhesive body may further include a third body; and the third body is located on a side of the second body facing away from the first body.

During implementation, a content of the target dopant in the third body is different from that in the second body.

For example, a content of the first-type graphene in the second body may be 9 wt % and a content of the first-type graphene in the third body may be 8 wt %. For another example, a content of the second-type graphene in the second body may be 11 wt % and a content of the second-type graphene in the third body may be 14 wt %.

The content of the target dopant in the second body is set to be different from that in the third body, which may help to adjust the characteristics of the buffer structure. For example, two sides of the buffer structure need to maintain specific adhesion, therefore, the first body and the third body need to have specific adhesion, and however, the second body as an intermediate layer has no rigid requirement to have specific adhesion, so that it is possible to improve the mechanical strength or thermal conductivity of the buffer structure by increasing the mechanical strength or thermal conductivity of the second body, with no need to consider the adhesion of the second body.

Certainly, the description is merely made in the specification of the present application by using an example in which the first body and the second body in which the contents of the target dopant are different, and/or the second body and the third body in which the contents of the target dopant are different, but the present application is not limited thereto, and in some other embodiments, the content of the target dopant in the first body may be the same as that in the second body, and/or the content of the target dopant in the second body may be the same as that in the third body.

In some embodiments, the target parameter of the second body may be greater than that of the first body and greater than that of the third body, thereby enhancing the target parameter characteristics of the buffer structure.

For example, if the target parameter is the thermal conductivity, the thermal conductivity of the second body is greater than that of the first body and greater than that of the third body. The second body is a body located between the first body and the third body in the buffer structure, so that the thermal conductivity of the second body may be directly increased with no need to consider the adhesion of the second body, thus effectively improving the overall thermal conductivity of the buffer structure.

As another optional implementation of the disclosure of the present application, embodiments of the present application further provide a display module, including the buffer structure as described in any of the above embodiments.

In some embodiments, the display module may further include a display panel located on a side of the buffer structure.

During implementation, as shown in FIG. 8, the buffer structure S may be located on the back of the display panel P (the side of a substrate of the display panel P facing away from a light-emitting side), playing a role of buffer protection.

In some embodiments, as shown in FIG. 9, the display module may further include a support layer Z, and the support layer Z is located on a side of the buffer structure S facing away from the display panel P.

During application, the support layer Z may be a film layer made of copper foil.

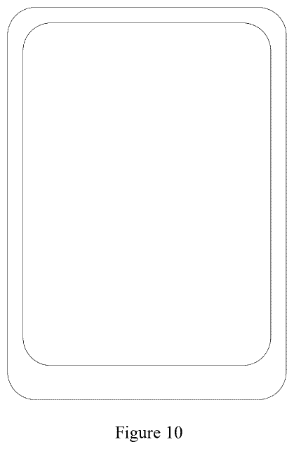

As an optional implementation of the disclosure of the present application, embodiments of the present application further provide a display device, and the display device includes: the display module as provided in any of the above embodiments. As shown in FIG. 10, FIG. 10 is a schematic diagram of a structure of a display device according to an embodiment of the present application, the display device may be a smartphone, a tablet computer, a digital camera, or the like, and details are not described herein.

The embodiments in the specification are described in a progressive manner. Each embodiment focuses on differences from other embodiments. For a part that is the same or similar between different embodiments, reference may be made between the embodiments.

With respect to the above description of the disclosed embodiments, those skilled in the art could implement or use the present application. Various modifications to these embodiments are apparent to those skilled in the art, and the general principle defined herein may be practiced in other embodiments without departing from the spirit or scope of the present application. Therefore, the present application is not limited to the embodiments described herein but is to be accorded with the broadest scope consistent with the principle and novel features disclosed herein.

What is claimed is:

1. A buffer structure, comprising:
a silicon-based pressure-sensitive adhesive layer, wherein
the silicon-based pressure-sensitive adhesive layer is doped with graphene.

2. The buffer structure according to claim 1, wherein
the graphene comprises a first-type graphene, wherein
the first-type graphene comprises an unmodified graphene; or
the graphene comprises a second-type graphene,
the second-type graphene comprises a modified graphene.

3. The buffer structure according to claim 1, wherein
the graphene comprises a first-type graphene and a second-type graphene,
the first-type graphene comprises an unmodified graphene,
the second-type graphene comprises a modified graphene,
wherein in the silicon-based pressure-sensitive adhesive layer, a content of the second-type graphene is greater than that of the first-type graphene.

4. The buffer structure according to claim 3, wherein the content of the first-type graphene ranges from 4 wt % to 10 wt %; or
the content of the first-type graphene is 6 wt %.

5. The buffer structure according to claim 3, wherein the content of the second-type graphene ranges from 5 wt % to 15 wt %; and
the modified graphene comprises graphene grafted with siloxane.

6. The buffer structure according to claim 3, wherein the silicon-based pressure-sensitive adhesive layer comprises a first sub-layer and a second sub-layer that are arranged in a stacked manner;
a content of the graphene in the first sub-layer is different from that in the second sub-layer; and
a film thickness of the first sub-layer is different from that of the second sub-layer.

7. The buffer structure according to claim 6, wherein the silicon-based pressure-sensitive adhesive layer further comprises a third sub-layer, and the third sub-layer is located on a side of the second sub-layer facing away from the first sub-layer;
a content of the graphene in the third sub-layer is different from that in the second sub-layer;
a film thickness of the third sub-layer is different from that of the second sub-layer;
the film thickness of the second sub-layer is greater than that of the first sub-layer and greater than that of the third sub-layer;
a thickness of the first sub-layer ranges from 5 μm to 40 μm;
a thickness of the second sub-layer ranges from 70 μm to 140 μm;
a thickness of the third sub-layer ranges from 5 μm to 40 μm; and
thermal conductivity of the second sub-layer is greater than that of the first sub-layer and greater than that of the third sub-layer.

8. The buffer structure according to claim 7, wherein the first sub-layer comprises a first silicon-based pressure-sensitive adhesive layer; the second sub-layer comprises a second silicon-based pressure-sensitive adhesive layer or a thermally conductive layer, and a content of silicon-based pressure-sensitive adhesive in the thermally conductive layer is 0; and the third sub-layer comprises a third silicon-based pressure-sensitive adhesive layer.

9. The buffer structure according to claim 8, wherein
the silicon-based pressure-sensitive adhesive in the first silicon-based pressure-sensitive adhesive layer, the second silicon-based pressure-sensitive adhesive layer, and the third silicon-based pressure-sensitive adhesive layer comprises silica gel;
the silica gel in the first silicon-based pressure-sensitive adhesive layer and the third silicon-based pressure-sensitive adhesive layer is platinum-catalyzed silica gel;
the silica gel in the second silicon-based pressure-sensitive adhesive layer is silica gel in which hydroxyl groups react with each other.

10. The buffer structure according to claim 8, wherein
when the silicon-based pressure-sensitive adhesive layer is doped with the second-type graphene, a content of the second-type graphene doped in the second sub-layer ranges from 12 wt % to 15 wt %;
a content of the second-type graphene doped in the first silicon-based pressure-sensitive adhesive layer ranges from 5 wt % to 11 wt %;
a content of the second-type graphene doped in the third silicon-based pressure-sensitive adhesive layer ranges from 5 wt % to 11 wt %;
when the silicon-based pressure-sensitive adhesive layer is doped with the first-type graphene, a content of the first-type graphene doped in the second sub-layer ranges from 8 wt % to 10 wt %;
a content of the first-type graphene doped in the first silicon-based pressure-sensitive adhesive layer ranges from 4 wt % to 7 wt %;
a content of the first-type graphene doped in the third silicon-based pressure-sensitive adhesive layer ranges from 4 wt % to 7 wt %; and
a material of the thermally conductive layer comprises a modified thermoplastic polyurethane elastomer.

11. The buffer structure according to claim 7, wherein the second sub-layer is doped with a thermally conductive filler;
the thermally conductive filler comprises at least one of boron nitride, aluminum nitride, and silicon carbide; and
a content of the thermally conductive filler in the second sub-layer ranges from 20% to 80%.

12. The buffer structure according to claim 1, wherein the silicon-based pressure-sensitive adhesive layer comprises a plurality of accommodation holes; and
the plurality of accommodation holes are filled with the graphene.

13. The buffer structure according to claim 1, wherein silicon-based pressure-sensitive adhesive in the silicon-based pressure-sensitive adhesive layer comprises silica gel; and
a thickness of the silicon-based pressure-sensitive adhesive layer ranges from 80 μm to 150 μm.

14. A buffer structure, comprising:
a silicon-based pressure-sensitive adhesive body; and
a target dopant, wherein the target dopant is doped in the silicon-based pressure-sensitive adhesive body, and a target parameter of the target dopant is greater than that of the silicon-based pressure-sensitive adhesive body, wherein the target parameter comprises a Young's modulus or a thermal conductivity.

15. The buffer structure according to claim 14, wherein
the silicon-based pressure-sensitive adhesive body comprises a silica gel body;
the target dopant comprises graphene;
the graphene comprises first-type graphene and second-type graphene, wherein
the first-type graphene comprises unmodified graphene; and the second-type graphene comprises modified graphene; wherein in the silicon-based pressure-sensitive adhesive body, a content of the second-type graphene is greater than that of the first-type graphene.

16. The buffer structure according to claim 14, wherein the silicon-based pressure-sensitive adhesive body comprises a first body and a second body that are arranged in a stacked manner; and
a content of the target dopant in the first body is different from that in the second body.

17. The buffer structure according to claim 16, wherein the silicon-based pressure-sensitive adhesive body further comprises a third body; and the third body is located on a side of the second body facing away from the first body;
a content of the target dopant in the third body is different from that in the second body; and
a target parameter of the second body is greater than that of the first body and greater than that of the third body.

18. A display module, comprising the buffer structure according to claim 1 further comprising a display panel located on a side of the buffer structure; and
further comprising a support layer located on a side of the buffer structure facing away from the display panel.

19. A display device, comprising the display module according to claim 18.
